(19) United States
(12) Patent Application Publication
(10) Pub. No.: US 2025/0105118 A1
(43) Pub. Date: Mar. 27, 2025

(54) ELECTRONIC DEVICE AND MANUFACTURING METHOD THEREOF

(71) Applicant: PanelSemi Corporation, New Taipei City (TW)

(72) Inventors: Tang-Chin HUNG, New Taipei City (TW); Chin-Tang LI, New Taipei City (TW); Hsien-Te CHEN, Taipei City (TW)

(21) Appl. No.: 18/899,738

(22) Filed: Sep. 27, 2024

Related U.S. Application Data
(60) Provisional application No. 63/585,746, filed on Sep. 27, 2023.

(51) Int. Cl. H01L 23/498; H01L 21/48; H01L 27/12

(52) U.S. Cl. CPC H01L 23/49822; H01L 21/4857; H10D 86/00

(57) ABSTRACT

An electronic device and a manufacturing method thereof are provided. The electronic device includes a redistribution structure configured with a redistribution layer trace; a substrate configured with a substrate trace facing the redistribution structure; an adhesion layer attaching the redistribution structure to the substrate; and a plurality of conductive members arranged at least through the adhesion layer and electrically connecting the RDL trace of the redistribution structure to the substrate trace of the substrate.

### CROSS REFERENCE TO RELATED APPLICATIONS

This Non-provisional application claims priority under 35 U.S.C. § 119(a) on Patent Application No(s). 63/585,746 filed in United States of America on Sep. 27, 2023, the entire contents of which are hereby incorporated by reference.

### BACKGROUND

### Technology Field

The disclosure relates to an electronic device and specifically refers to an electronic device with board assembly applicable to the redistribution structure.

### Description of Related Art

Conventional wafer manufacturers are eager and tries to Scale up the feature size of the chip through RDL (redistribution layer) as much as possible, and then package the whole functions, in which the processes are made in the wafer fab. However, for the substrate manufacturers, to maintain both of benefits of enhancing the precision of the substrate and reducing the feature size is not only another approach in combination with the wafer package and the substrate but also a must-do in the semiconductor industry.

### SUMMARY

This disclosure provides an electronic device and a manufacturing method thereof, which are intended to facilitate substrate manufacturers to obtain the benefits of flexibility in combination with substrates and components.

An electronic device is disclosed, which comprises a redistribution structure configured with a redistribution layer trace, a substrate configured with a substrate trace facing the redistribution structure, an adhesion layer attaching the redistribution structure to the substrate; and a plurality of conductive members arranged at least through the adhesion layer and electrically connecting the RDL trace of the redistribution structure to the substrate trace of the substrate.

A manufacturing method for the electronic device are also disclosed, which comprises the steps of: forming a redistribution wiring structure on a base substrate, in which the redistribution wiring structure is configured with an initial trace; attaching the redistribution wiring structure to a substrate configured with a substrate trace, wherein the substrate trace faces to the redistribution wiring structure; removing at least partial of the base substrate; arranging an adhesion layer and a plurality of conductive members between the redistribution wiring structure and the substrate before attaching the redistribution wiring structure to the substrate; and the electronic device is accomplished. A redistribution structure is defined after removing at least partial of the base substrate and the redistribution structure is configured with a redistribution layer (RDL) trace, and the conductive members electrically connect the RDL trace of the redistribution structure to the substrate trace of the substrate.

Another manufacturing method is also provided, which comprises the steps of: forming a redistribution wiring structure on a base substrate, in which the redistribution wiring structure is configured with an initial trace; removing at least partial of the base substrate; arranging an adhesion layer and a plurality of conductive members between the redistribution wiring structure and the substrate before attaching the redistribution wiring structure to the substrate; attaching the redistribution wiring structure to a substrate configured with a substrate trace, wherein the substrate trace faces to the redistribution wiring structure; and the electronic device is accomplished. A redistribution structure is defined after removing at least partial of the base substrate and the redistribution structure is configured with a redistribution layer (RDL) trace, and the conductive members electrically connect the RDL trace of the redistribution structure to the substrate trace of the substrate.

In one embodiment, the RDL trace of the redistribution structure defines a RDL trace width, and the substrate trace of the substrate defines a substrate trace width; in a vicinity of one or ones of at least partial of the conductive members, the RDL trace width is less than the substrate trace width.

In one embodiment, the redistribution structure defines a RDL thickness while the substrate defines a substrate thickness; a ratio of the substrate thickness to the RDL thickness is no less than 5 but not limited thereto, e.g. no less than 1, 2, 3, 4, or 5.

In one embodiment, the RDL trace of the redistribution structure defines an average thickness, and the substrate trace of the substrate defines an average thickness; the average thickness of the RDL trace is less than the average thickness of the substrate trace.

In one embodiment, the redistribution structure defines an average thickness, and the substrate defines an average thickness; the average thickness of the redistribution structure is less than the average thickness of the substrate.

In one embodiment, the electronic device further includes one or more thin-filmed device(s) formed on the redistribution structure and electrically connected to the RDL trace.

In one embodiment, the redistribution structure defines two opposite surfaces, and one or ones of thin-filmed device(s) is (are) formed on either or both of two surfaces of the redistribution structure.

In one embodiment, partial of the RDL trace is provided with a thickness no greater than 10 μm.

In one embodiment, the RDL trace of the redistribution structure defines an RDL trace width, and partial of the RDL trace width is no greater than 50 μm.

In one embodiment, the redistribution structure includes one or more sub-trace layer(s) stacked thereover.

In one embodiment, the redistribution structure includes an insulating structure jointly with adjacent two of the sub-trace layers.

In one embodiment, each of the substrate and the redistribution structure defines a coefficient of thermal expansion (CTE), and a difference of CTE between the substrate and the redistribution structure is no greater than 30 ppm/° C.

In one embodiment, the substrate is a glass substrate, a ceramic substrate, a bismaleimide triazin laminated (BT) substrate, a fiberglass-reinforced epoxy-laminated (FR4) substrate, an ajinomoto build-up film (ABF) substrate, or Rogers substrate, PI substrate.

In one embodiment, the base substrate includes a rigid board and a resilient board stacked over the rigid board; the redistribution wiring structure is formed on the resilient board with the initial trace, and the initial trace is away from the rigid board; in addition, the rigid board is removed from the resilient board in the step of removing at least partial of the base substrate, and the redistribution structure comprises the resilient board and the redistribution wiring structure.

In one embodiment, the base substrate includes a rigid board, and the redistribution wiring structure is formed on the rigid board and provided with the initial trace, and the initial trace faces to the substrate when attaching the redistribution wiring structure to the substrate; in addition, the rigid board is removed from one surface the redistribution wiring structure in the step of removing at least partial of the base substrate, and an additional trace and/or pads are arranged on the surface of the redistribution wiring structure, wherein the redistribution wiring structure is considered as at least partial of the redistribution structure, and the additional trace may denote at least partial of the RDL trace of the redistribution structure after the rigid board is removed.

In one embodiment, before the at least partial of the base substrate is removed, a temporary molding structure is molded to cover at least partially of the initial trace of the redistribution wiring structure; and the temporary molding structure is removed from the redistribution wiring structure after the redistribution wiring structure is attached to the substrate.

In one embodiment, a plurality of pads are formed on the redistribution wiring structure before the temporary molding structure is molded, and the pads electrically connect the initial trace; and a plurality of substrate pads is formed on the substrate before the redistribution wiring structure is attached to the substrate, and the substrate pads electrically connect the substrate trace.

### BRIEF DESCRIPTION OF THE DRAWINGS

FIG. 1 to FIG. 3 are flow charts showing manufacturing methods for an electronic device;

FIG. 4 to FIG. 7 are schematic diagrams showing process for manufacturing an electronic device; and

FIG. 8 are schematic diagrams showing structures of four electronic devices manufactured by the process in FIG. 4 to FIG. 7.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

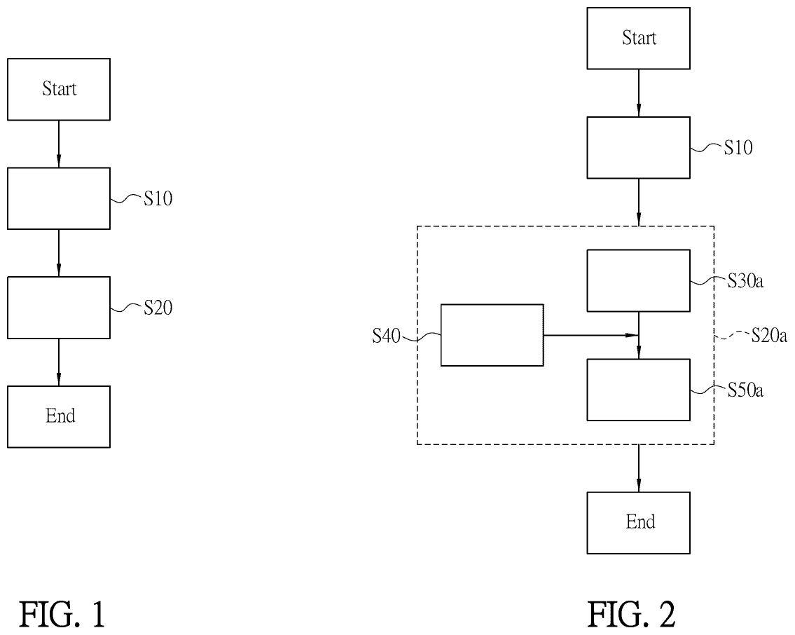

FIG. 1 is a flow chart of manufacturing method for an electronic device. The manufacturing method includes at least two steps: in step S10, a redistribution wiring structure is formed on a base substrate, and in step S20, the redistribution wiring structure is attached to a substrate, at least partial of the base substrate is removed from the redistribution wiring structure. An adhesion layer and a plurality of conductive members are arranged between the redistribution wiring structure and the substrate in or between the steps S10 and 20. In some cases, the redistribution wiring structure ca be formed by a thin film process on the base substrate, but not limited thereto.

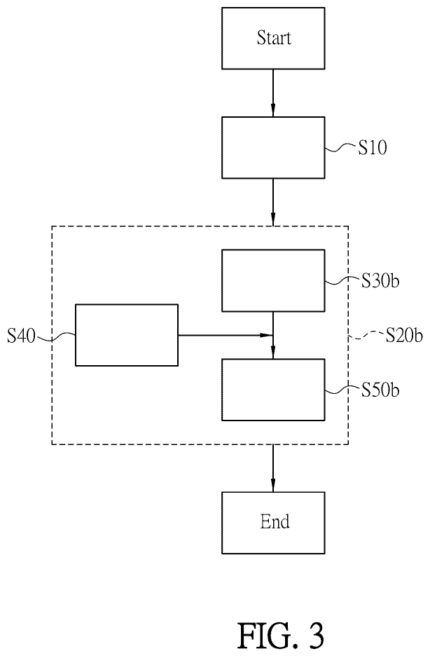

The manufacturing methods can be enforced into various types, and most likely can be divided into two mainly types in FIG. 2 and FIG. 3.

In FIG. 2, the step S20a includes steps S30a, S40, and S50a, the step S30a is removing at least partial of the base substrate, step S50a is attaching the redistribution wiring structure to a substrate configured with a substrate trace, wherein the substrate trace faces to the redistribution wiring structure, and the step S40 is arranging an adhesion layer and a plurality of conductive members between the redistribution wiring structure and the substrate before attaching the redistribution wiring structure to the substrate.

In FIG. 3, the step S20b includes steps S30b, S40, and S50b. The step S30b is attaching the redistribution wiring structure to a substrate configured with a substrate trace, wherein the substrate trace faces to the redistribution wiring structure; the step S50b is removing at least partial of the base substrate, and the step S40 is arranging an adhesion layer and a plurality of conductive members between the redistribution wiring structure and the substrate before attaching the redistribution wiring structure to the substrate.

For further comprehension, there are more embodiments are introduced as followed.

### Embodiment 1

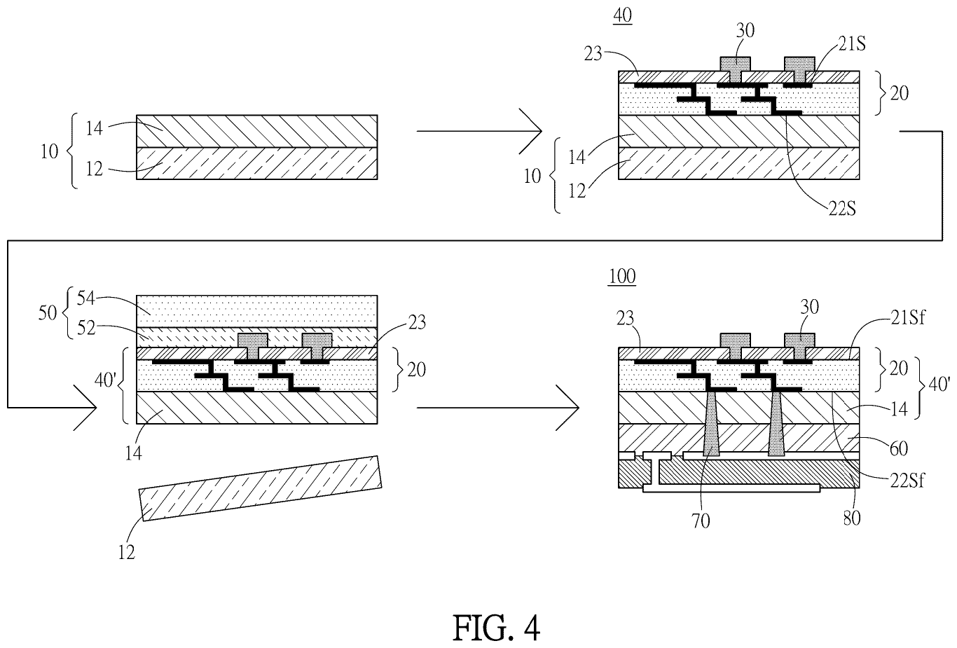

FIG. 4 is one embodiment of manufacturing an electronic device by the steps in FIG. 2. In the step S10, a redistribution wiring structure 20 is implementing on a base substrate 10, the base substrate 10 includes a rigid board 12 and a resilient board 14 stacked over the rigid board 12. A temporary redistribution structure 40 is formed after the redistribution wiring structure 20 is arranged on the resilient board 14 of the base substrate 10, and at least one initial trace is formed with the redistribution wiring structure 20.

In one case, the at least one initial trace may be formed of thin film by a thin film process, in which partial of the at least one initial trace is provided with a thickness no greater than 10 μm. If the quantity of the initial trace is more than one, there may be at least one of the initial traces formed of thin film as well. In one case, the at least one initial trace defines a thickness of partial segment thereof may be no greater than 5 μm. In one case, a first initial trace 21S and a second initial trace 22S are formed on two opposite surfaces of the redistribution wiring structure 20, the first initial trace 21S is away from the resilient board 14, and the second initial trace 22S faces the resilient board 14. A plurality of pads are arranged on one surface of the redistribution wiring structure 20 opposite to the base substrate 10, and the electrically connects a sub-trace layer (, which is elaborated in next paragraph). In addition, an insulation layer 23 is optionally provided on one surface of the redistribution wiring structure 20 opposite to the base substrate 10, and the pads electrically connects the sub-trace layer through via or the like.

In one case, the redistribution wiring structure 20 includes one or more sub-trace layers stacked thereover. In addition, the redistribution wiring structure 20 further includes an insulating structure arrange between adjacent two of the sub-trace layers. In one case, an insulating structure may also be applied to one single sub-trace layer, in order to fill a gap between wirings of the at least one sub-trace layers. Instead of the insulation layer 23, the insulating structure may further be arranged higher than the most-top sub-trace layer, and the pad electrically connects the sub-trace layer through a via or the like.

In one case, either or both of the rigid board 12 and the resilient board 14 can be a one-single-layer substrate. The rigid board 12 can be made of glass materials or ceramic materials but not limited thereto. The resilient board 14 may be and made of polyimide (PI), polyether ether ketone (PEEK), polyethylene naphthalatep (PET), polytetrafluoroethylene (PTFE), liquid crystal polymer (LCP), aramid fiber materials or the like.

In one case, the rigid board 12 can be a one-single-layer substrate. The rigid board 12 can be made of glass materials or ceramic materials. In one case, an insulating structure may be made of polyimide (PI) materials or other materials similar to options of the resilient board 14.

Before the step S30a in FIG. 2 of removing at least partial of the base substrate 10 of the temporary redistribution structure 40, some steps can be also performed. One step is arranging a plurality of first pads 30 on the surface of the redistribution wiring structure 20 opposite to the base substrate 10 for electrically connecting the at least one initial trace, herein, the first initial trace 21S. The temporary redistribution structure 40 in this step is further concluded with the first pads 30.

Another step before performing the step S30a is arranging a temporary molding structure 50 to cover on the redistribution wiring structure 20 and the first pads 30. The temporary molding structure 50 may include an insulation molding layer 52 and a supporting board 54; the insulation molding layer 52 covers the surface configured with the first pads 30 of the redistribution wiring structure 20, and the supporting board 54 joints the insulation molding layer 52 and is away from the redistribution wiring structure 20. The temporary redistribution structure 40 in this step is further concluded with the temporary molding structure 50.

In the step 30a of removing at least partial of the base substrate 10, the rigid board 12 is removed from the resilient board 14 of the temporary redistribution structure 40, due to the insulation molding layer 52 being held stably.

Before or after the step S50a of attaching the temporary redistribution structure 40 to a substrate 80, the temporary molding structure 50 (the insulation molding layer 52 and the supporting board 54) is removed from the redistribution wiring structure 20. The temporary redistribution structure 40 now in this step is concluded only with the redistribution wiring structure 20 and the resilient board 14, and is denoted a redistribution structure 40′.

The substrate 80 is configured with a substrate trace facing the redistribution structure 40′.

Before or in the step S50a of attaching the temporary redistribution structure 40 to the substrate 80, an adhesion layer 60 and a plurality of conductive members 70 are arranged between the temporary redistribution structure 40 and the substrate 80 for electrically connecting the initial trace of the redistribution wiring structure 20 to the substrate trace of the substrate 80.

There are several approaches to arrange the adhesion layer 60 and the conductive members 70. The adhesion layer 60 can be apply to the temporary redistribution structure 40 or the substrate 80, and then conductive members 70 are arranged. In another approach, the adhesion layer 60 is applied to both of the temporary redistribution structure 40 and the substrate 80, then the conductive members 70 arranged. In another approach, the conductive members 70 are arranged before applying the adhesion layer 60. In another approach, the conductive members 70 are assembled by two segments, which are arranged on both of the temporary redistribution structure 40 and the substrate 80 respectively, and then to join the two segments of the conductive members 70 together. In alternative approach, the conductive members 70 are assembled by two segments, which are arranged on both of the temporary redistribution structure 40 and the substrate 80 simultaneously, with configurations including, but not limited to, a radial arrangement with inner-and-outer allocation. However, the approach for arranging the adhesion layer 60 and the conductive members 70 are not limited by the above-mentioned approaches.

In other words, the priority to perform the step of removing the temporary molding structure 50 and the step of arranging the adhesion layer 60 and the conductive members 70 is not limited. Also, in other words, the priority to perform the step of arranging the adhesion layer 60 and the step of implementing the conductive members 70 is not limited.

In the step S50a of attaching the temporary redistribution structure 40 to the substrate 80; the substrate 80 can be a glass substrate, a ceramic substrate, a bismaleimide triazin laminated (BT) substrate, a fiberglass-reinforced epoxy-laminated (FR4) substrate, an ajinomoto build-up film (ABF) substrate, or Rogers substrate, but not limited thereto. The substrate 80 may be formed of resilient materials, similar to options of the resilient board 14, as well. In one case, the substrate 80 is a one-single-layered substrate or a multi-layered substrate.

As the redistribution structure 40′ is provided, the redistribution structure 40′ defines two opposite surfaces 21Sf and 22Sf, the first initial trace 21S is be denoted as a redistribution layer trace (RDL trace), and the pads 30, which electrically connect the RDL trace, are denoted as RDL pads. An electronic device 100, which at least includes the redistribution structure 40′ and substrate 80, is accomplished.

In addition, one or more thin-filmed device(s) is (are) formed on either one of the two opposite surfaces of the temporary redistribution structure 40 (or the redistribution structure 40′) before or after the step S50a (attaching the temporary redistribution structure 40 to the substrate 80). The thin-filmed device(s) is (are) used to electrically connect with the first initial trace 21S or the second initial trace 22S (two RDL traces). In one case, the thin-filmed device includes either or both of an active circuit and a passive circuit.

In one case, one or more of the substrates 80, the redistribution wiring structure 20, and the adhesion layer 60 is (are) different materials from others; which means they may be chosen from different material, but not limited thereto. In other words, they can be chosen from similar of material.

In one case, one or more of the substrates 80, the redistribution wiring structure 20, and the adhesion layer 60 is/are rigid, but not limited thereto. In other words, one or more of the substrates 80, the redistribution wiring structure 20, and the adhesion layer 60 is/are resilient.

The substrate 80, the redistribution wiring structure 20, the rigid board 12 and the resilient board 14 of the base substrate 10 define their own coefficient of thermal expansion (CTE). In one case, a difference between the CTE of the substrate 80 and the CTE of the redistribution wiring structure 20 is no greater than 30 ppm/° C., but not limited thereto, for example, the difference between the CTE of the substrate 80 and the CTE of the redistribution wiring structure 20 is no greater than 20 ppm/° C., 10 ppm/° C., or 5 ppm/° C.

In one case, a difference between the CTE of the rigid board 12 and the resilient board 14 of the base substrate 10 is no greater than 30 ppm/° C. In one case, a difference between the CTE of the base substrate 10 and the redistribution wiring structure 20 is no greater than 30 ppm/° C.

### Embodiment 2

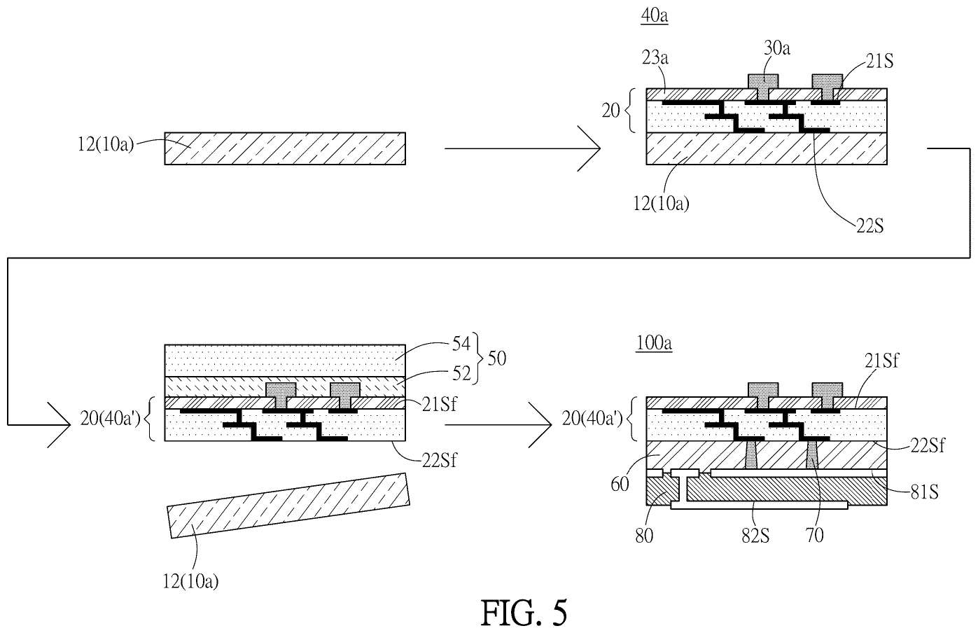

FIG. 5 is another embodiment of manufacturing an electronic device by the steps in FIG. 2. The differences between the embodiment in FIG. 4 and in FIG. 5 is that the base substrate 10a in FIG. 5 only includes a rigid board 12, so that a temporary redistribution structure 40a here only includes a redistribution wiring structure 20 and the rigid board 12. A redistribution structure 40a′ in this embodiment is concluded with the redistribution wiring structure 20 without the rigid board 12. At least one first pad 30 can be provided to one surface of the redistribution wiring structure 20 opposite to the base substrate 10a. An insulation layer 23a is optionally provided to the one surface of the redistribution wiring structure 20 opposite to the base substrate 10a. To be noted, the insulation layer 23, 23a disclosed in this invention can be instead of the insulating structure of the insulating structure, and similar element and numerals thereof will not be elaborated further.

Similar to the embodiment in FIG. 4, the steps of arranging a plurality of first pads 30 on the redistribution wiring structure 20 and/or arranging a temporary molding structure 50 to cover on the redistribution wiring structure 20 and the first pads 30 can be performed before the step S30a in FIG. 2. The temporary molding structure 50 in this embodiment can also include the insulation molding layer 52 and the supporting board 54. The temporary redistribution structure 40a′ here in this case is further concluded with the temporary molding structure 50. The redistribution structure 40a′ defines two opposite surfaces 21Sf and 22Sf, and the redistribution structure 40a′ is attached to the substrate 80 by the surface 22Sf.

In this embodiment, the step of removing the temporary molding structure 50, the approaches to arranging the adhesion layer 60 and a plurality of conductive members 70, and the step 50a are also similar to the embodiment of FIG. 4.

The electronic device is obtained after the step S50a. The configuration and/or the material used of this electronic device can be similar to the electronic device in FIG. 4, but the electronic device in FIG. 5 does not have the resilient board 14 between the redistribution wiring structure 20 and the substrate 80.

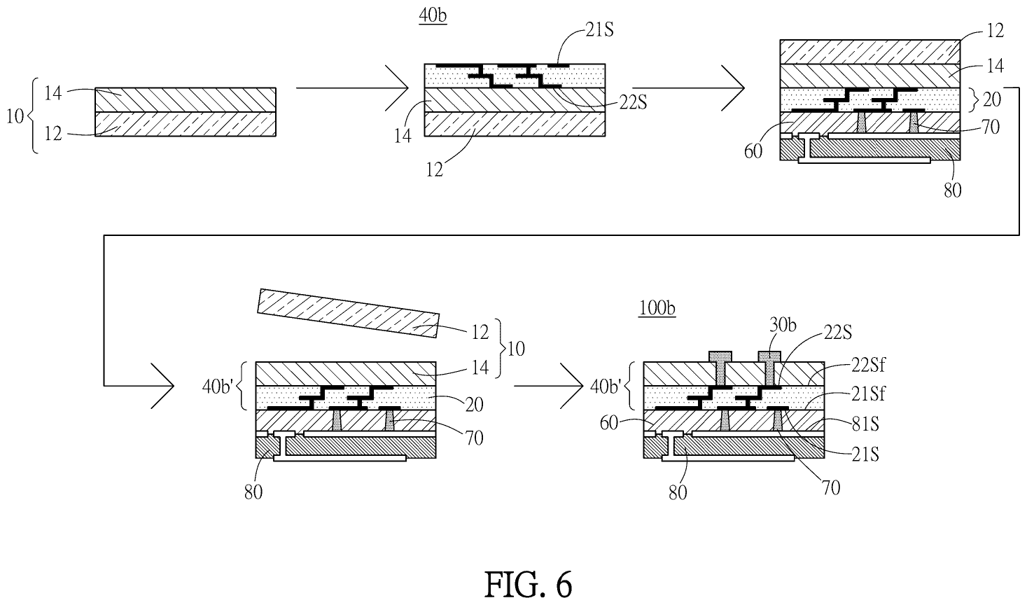

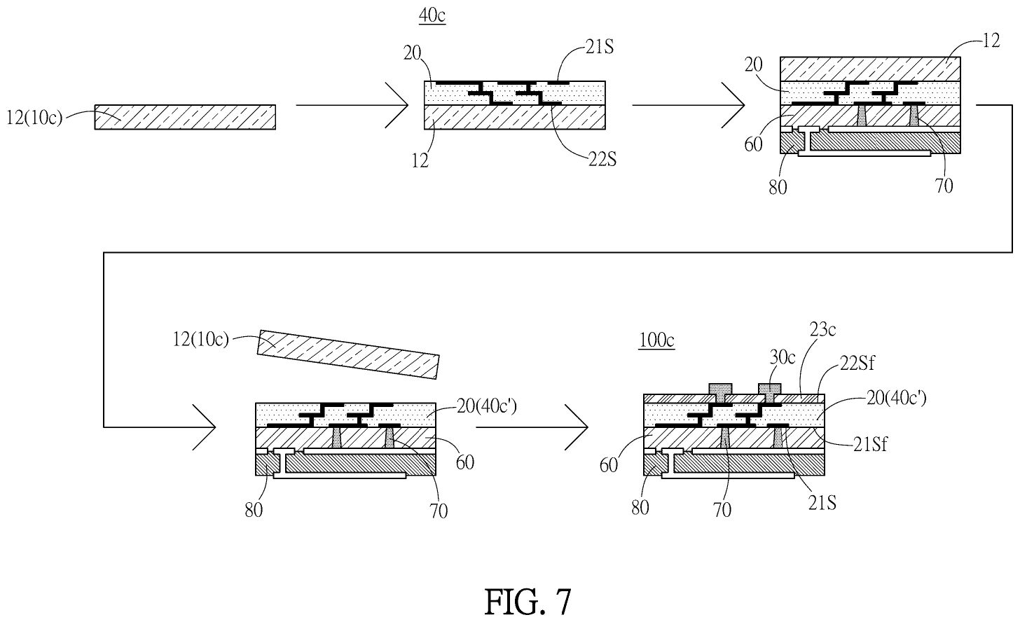

A third and a fourth embodiment are elaborated in FIG. 6 and FIG. 7 which are manufactured by method referred in FIG. 3.

In FIG. 3, the step S20b includes steps S30b, S40, and S50b. The step S30b is attaching the redistribution wiring structure to a substrate configured with a substrate trace, wherein the substrate trace faces to the redistribution wiring structure; the step S50b is removing at least partial of the base substrate from the redistribution wiring structure, and the step S40 is arranging an adhesion layer and a plurality of conductive members between the redistribution wiring structure and the substrate before attaching the redistribution wiring structure to the substrate.

### Embodiment 3

In this embodiment, the electronic device is manufactured by the steps shown in FIG. 3. In the step S10, a redistribution wiring structure 20 is arranged on the base substrate 10, the base substrate 10 includes a rigid board 12 and a resilient board 14 stacked over the rigid board 12. A temporary redistribution structure 40b is concluded after the redistribution wiring structure 20 is arranged on the base substrate 10. The redistribution wiring structure 20 is configured with at least one initial trace, and the at least one initial trace may be formed of thin film. Partial of the at least one initial trace is provided with a thickness no greater than 10 μm. Furthermore, if the redistribution wiring structure 20 comprise plural initial traces, at least one of the initial traces is formed of thin film as well. In one case, the at least one initial trace defines a thickness and at least partial thickness thereof is no greater than 5 μm. In one case, a first initial trace 21S and a second initial trace 22S may be formed on two surfaces of the redistribution wiring structure 20, the first initial trace 21S is away from the resilient board 14, and the second initial trace 22S faces the resilient board 14.

In one case, the redistribution wiring structure 20 includes one or more sub-trace layers stacked thereover; in one case, the redistribution wiring structure 20 further includes one insulating structure may be provided to joint with adjacent two of the sub-trace layers. In one case, an insulating structure may also be applied to one single sub-trace layer, in order to fill a gap between wirings of the at least one initial trace.

The materials or the characters of the rigid board 12 and the resilient board 14 in this embodiment may be similar to the rigid board 12 and the resilient board 14 in the above-mentioned embodiments.

Before or in the step S30b of attaching the temporary redistribution structure 40 to a substrate 80, an adhesion layer 60 and a plurality of conductive members 70 are arranged between the temporary redistribution structure 40b and the substrate 80.

The approaches to arrange the adhesion layer 60 and the conductive members 70 are similar to the above-mentioned approaches in the Embodiment 1 and the Embodiment 2, but is not limited thereto.

In the step S30b of attaching the temporary redistribution structure 40b to the substrate 80, the first initial trace 21S of the redistribution wiring structure 20 is flipped to faces and to stack over the substrate 80.

In the step S50b of removing at least partial of the base substrate 10, the rigid board 12 is removed from the resilient board 14; at the meantime, the substrate 80 has been attached to the redistribution wiring structure 20 already. The temporary redistribution structure 40b now in this stage is concluded only with the redistribution wiring structure 20 and the resilient board 14, and is denoted a redistribution structure 40b′.

After the step S50b in which the rigid board 12 is removed from the resilient board 14, an additional trace and/or a plurality of pads 30b can be formed on and/or in a surface of the resilient board 14 opposite to the redistribution wiring structure 20, the pads 30b pass through the resilient board 14 and electrically connects the additional trace to the second initial trace 22S. A redistribution structure 40b′ concluded with the additional trace and/or the additional pads are formed. In this embodiment, the resilient board 14 can be considered as an insulation layer.

The redistribution structure 40b′ defines two opposite surfaces 21Sf and 22Sf, the additional trace on the resilient board 14 forms at least partial of a redistribution layer (RDL) trace, and the pads 30b on the resilient board 14, which electrically connect the RDL trace, are denoted as at least partial of the RDL pads. An electronic device 100b, which at least includes the redistribution structure 40b′ and substrate 80, is accomplished.

Before the step S30b (attaching the temporary redistribution structure 40 to the substrate 80) or after the step S50b (removing at least partial of the base substrate 10), one or more thin-filmed devices are formed on either one or both of the two opposite surfaces of the initial redistribution structure 40b or the redistribution structure 40b′ for electrically connection with the first initial trace 21S or the second initial trace 22S (two RDL traces). In one case, the thin-filmed device includes either or both of an active circuit and a passive circuit.

In this embodiment, the first initial trace 21S here is arranged between the substrate 80 and redistribution wiring structure 20, while the second initial trace 22S is arranged between the redistribution wiring structure 20 and the resilient board 14.

### Embodiment 4

FIG. 7 shows another embodiment of manufacturing the electronic device by the method shown in FIG. 3.

The manufacturing method in this embodiment is similar to the manufacturing method in the Embodiment 3. However, the major differences between the steps in this embodiment and the steps in the Embodiment 3 is described as follows: the base substrate 10 in this embodiment only includes a rigid board 12, so a temporary redistribution structure 40c includes a redistribution wiring structure 20 and the rigid board 12. However, after the rigid board 12 is removed after the step 50b, the redistribution structure 40c′ is concluded with the redistribution wiring structure 20 without the rigid board 12. Further, the redistribution structure 40c′ also defines two opposite surfaces 21Sf and 22Sf, in which the redistribution structure 40c′ attaches to the substrate by the surface 21Sf. In addition, a plurality of additional pads 30c are provided on the surface 22Sf opposite to the surface 21Sf, and electrically connect to the initial trace(s) of the redistribution wiring structure 20. Furthermore, an insulation layer 23c is optionally provided on the surface 22Sf opposite to the surface 21Sf, and the additional pads 30c pass through the insulation layer 23c for electrically connection.

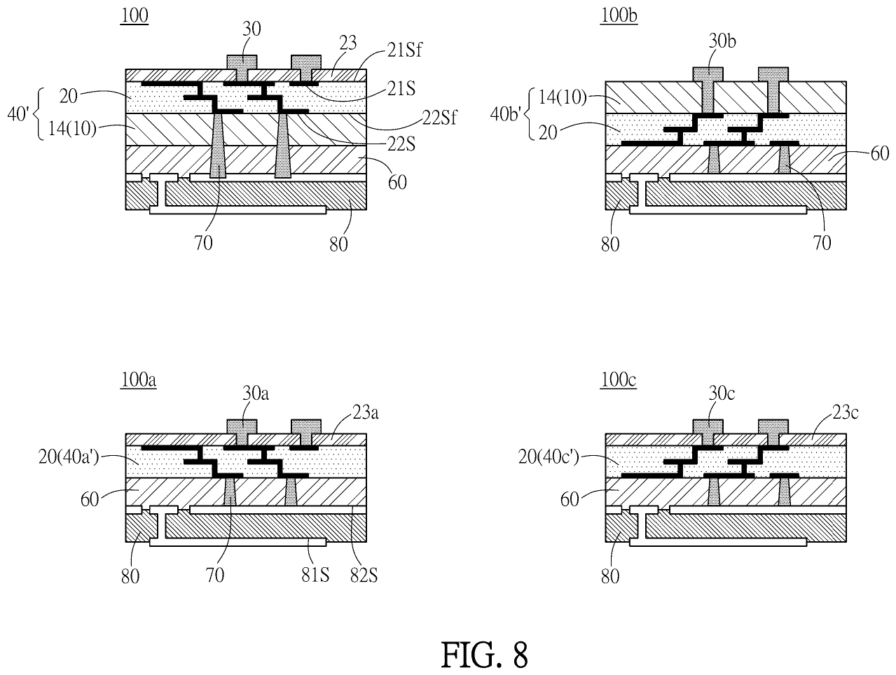

Referring to FIG. 8, structures of the four electronic devices 100, 100a, 100b, 100c are provided, in which they are respectively manufactured by the methods shown in FIG. 4 to FIG. 7. Each of the four electronic devices 100, 100a, 100b, 100c comprises a substrate 80, a redistribution structure 40′, 40a′, 40b′, 40c′, an adhesion layer 60, and a plurality of conductive members 70.

The substrate 80 defining two opposite surfaces, and a substrate trace formed on one of the two surfaces; wherein the substrate trace is provided with a substrate trace width.

The redistribution structure 40′, 40a′, 40b′, 40c′ is arranged over the substrate 80; wherein the redistribution structure 40′, 40a′, 40b′, 40c′ is configured with a redistribution layer (RDL) trace.

The adhesion layer 60 is arranged between the redistribution structure redistribution structure 40′, 40a′, 40b′, 40c′ and the substrate 80. The conductive members 70 are arranged at least through the adhesion layer 60 and electrically connecting the RDL trace of the redistribution structure 40′, 40a′, 40b′, 40c′ to the substrate trace of the substrate 80.

In one case, partial of the first trace width of the first initial trace is no greater than 50 μm; in one case, partial of the first trace width of the first initial trace is no greater than 20 μm; in one case, partial of the first trace width of the first initial trace is no greater than 10 μm; in one case, partial of the first trace width of the first initial trace is no greater than 5 μm.

The RDL trace of the redistribution structure 40′, 40a′, 40b′, 40c′ defines a RDL trace width while the substrate trace of the substrate 80 defines a substrate trace width; in a vicinity of one or ones of the conductive members 70, the RDL trace width is less than the substrate trace width. In addition, the redistribution structure 40′, 40a′, 40b′, 40c′ also defines a RDL line space, and the substrate 80 also defines a substrate line space, and at least partial of the RDL line space is not great than the substrate line space. In some cases, the RDL trace width is greater than the trace width of the substrate, and the RDL line space is not greater than the substrate line space. In some cases, the RDL trace width is not greater than the trace width of the substrate, and the RDL line space is greater than the substrate line space.

The redistribution structure 40′, 40a′, 40b′, 40c′ defines a RDL thickness while the substrate 80 defines a substrate thickness; a ratio of the substrate thickness over the RDL thickness is no greater than 10.

The redistribution structure 40′, 40a′, 40b′, 40c′ includes one or more sub-trace layers stacked thereover, the redistribution structure 40′, 40a′, 40b′, 40c′ further includes an insulating structure jointed with adjacent two of the sub-trace layers. In one case, an insulating structure may also be applied to one single sub-trace layer, in order to fill a gap between wirings of the at least one sub-trace layer.

The substrate 80 includes a plurality of substrate pads (not shown in FIGs) electrically connecting the substrate trace, and the redistribution structure 40′, 40a′, 40b′, 40c′ includes a plurality of RDL pads (not shown in FIGs) facing substrate 80 and electrically connecting the substrate pads in a respective manner. Each of the substrate pads and RDL pads is defined with a measured area, and the measured area of the RDL pads may be no less than the measured area of the substrate pads in some cases.

In one case shown as the electronic device 100 in FIG. 8, the redistribution structure defines two opposite surfaces, a first initial trace 21S is formed on one surface 21Sf away from the substrate 80, and a second initial trace 22S is formed on the other surface 22Sf facing the substrate 80. The first initial trace 21S is provided with a first trace width (also denotes as RDL trace here), the second initial trace 22S is formed of thin film and provided with a second trace width (as another RDL trace). The adhesion layer 60 attaches the redistribution structure 40 to the substrate 80; and the conductive members 70 are arranged in the adhesion layer 60 and electrically connecting the second initial trace 22S of the redistribution structure 40′, to the substrate trace of the substrate 80.

In one case, the substrate trace of the substrate either faces or is away from the redistribution structure. In one case shown as the electronic device 100a in FIG. 8, two substrate traces 81S, 82S of the substrate 80 are formed thereof. In one case, any one of the substrate traces of the substrate 80 is formed of thin-film, in which partial of the substrate traces of the substrate 80 is provided with a thickness no greater than 10 μm.

The substrate 80 includes a plurality of substrate pads electrically connecting the substrate trace, and the redistribution structure 40′, 40a′, 40b′, 40c′ includes a plurality of first pads and second pads electrically connecting the first initial trace 21S and the second initial trace 22S in a respective manner; each of the first pads, the second pads and the substrate pads may be defined with a measured area. In one case, the measured area of the second pads may be no less than the measured area of the substrate pads, one or ones of the first pads are less than a measured area of one or ones of the substrate pads.

To be noted, the pads with numerals in this invention denotes the pads for out bonding with additional electronic component(s) or substrate(s); some pads without illustration and numerals may exist for electrically connecting the conductive members 70.

It should be noted that the surface on which the first initial trace 21S is located may refer to either the surface 21Sf or the surface 22Sf of the redistribution wiring structure 20. This depends on the manufacturing method employed and should be reasonably understood in the current invention.

Accordingly, this disclosure provides a manufacturing method for an electronic device, which involves forming a redistribution wiring structure on a base substrate, attaching the redistribution structure to a substrate by an adhesion layer and conductive members. After the removal of part of the base substrate, the redistribution structure and the electronic device are acquired. The electronic device is benefit from both of delicate or fragile features of the redistribution structure, and thick or strong features of the substrate. Furthermore, the process is beneficial for substrate manufacturers as it enhances the precision of the substrate and reduces feature size. This method is not only a combination of wafer package and substrate, but is also increasingly essential in the semiconductive member industry.

What is claimed is:

1. An electronic device, comprising:
a redistribution structure configured with a redistribution layer (RDL) trace;
a substrate configured with a substrate trace facing the redistribution structure;
an adhesion layer attaching the redistribution structure to the substrate; and
a plurality of conductive members arranged at least through the adhesion layer and electrically connecting the RDL trace of the redistribution structure to the substrate trace of the substrate.

2. The electronic device as claimed in claim 1, wherein the RDL trace of the redistribution structure defines a RDL trace width while the substrate trace of the substrate defines a substrate trace width; in a vicinity of one or ones of the conductive members, the RDL trace width is less than the substrate trace width.

3. The electronic device as claimed in claim 1, wherein the redistribution structure defines a RDL thickness, and the substrate defines a substrate thickness, wherein a ratio of the substrate thickness to the RDL thickness is no less than 5.

4. The electronic device as claimed in claim 1, wherein the redistribution structure defines an average thickness of the RDL trace, and the substrate defines an average thickness of the substrate trace; wherein the average thickness of the RDL trace is less than the average thickness of the substrate trace.

5. The electronic device as claimed in claim 1, wherein the redistribution structure defines two opposite surfaces, and one or ones of thin-filmed device(s) are arranged on either or both of the two surfaces of the redistribution structure.

6. The electronic device as claimed in claim 1, wherein the redistribution structure includes one or more sub-trace layer(s) stacked thereover.

7. A manufacturing method for an electronic device, comprising:
forming a redistribution wiring structure configured with an initial trace on a base substrate;
removing at least partial of the base substrate;
attaching the redistribution wiring structure to a substrate configured with a substrate trace, wherein the substrate trace faces to the redistribution wiring structure;
arranging an adhesion layer and a plurality of conductive members between the redistribution wiring structure and the substrate before attaching the redistribution wiring structure to the substrate; and
wherein the electronic device is accomplished;
wherein a redistribution structure is defined after removing at least partial of the base substrate and the redistribution structure is configured with a redistribution layer (RDL) trace, and the conductive members electrically connect the RDL trace of the redistribution structure to the substrate trace of the substrate in which the initial trace forms at least partial of the RDL trace.

8. The manufacturing method for an electronic device as claimed in claim 7, wherein the RDL trace of the redistribution structure defines a RDL trace width and the substrate trace of the substrate defines a substrate trace width; in a vicinity of one or ones of the conductive members, the RDL trace width is less than the substrate trace width.

9. The manufacturing method for an electronic device as claimed in claim 7, wherein the redistribution structure defines a RDL thickness while the substrate defines a substrate thickness; a ratio of the substrate thickness to the RDL thickness is no less than 5.

10. The manufacturing method for an electronic device as claimed in claim 7, wherein the redistribution structure defines an RDL average thickness, and the substrate defines a substrate average thickness; the RDL average thickness is less than the substrate average thickness.

11. The manufacturing method for an electronic device as claimed in claim 7, wherein partial of the RDL trace is provided with a thickness no greater than 10 μm.

12. The manufacturing method for an electronic device as claimed in claim 7, wherein the RDL trace of the redistribution structure defines a RDL trace width, and partial of the RDL trace width is no greater than 50 μm.

13. The manufacturing method for an electronic device as claimed in claim 7, wherein the base substrate includes a rigid board and a resilient board stacked over the rigid board; the redistribution wiring structure is formed on the resilient board with the initial trace, and the initial trace is away from the rigid board.

14. The manufacturing method for an electronic device as claimed in claim 13, wherein the rigid board is removed from the resilient board in the step of removing at least partial of the base substrate, wherein after the step of removing at least partial of the base substrate, at least one pad is formed on and/or passes through the resilient board, and wherein the redistribution structure comprises the resilient board and the redistribution wiring structure.

15. The manufacturing method for an electronic device claimed in claim 7, wherein the base substrate includes a rigid board; the redistribution wiring structure is formed on the rigid board and provided with the initial trace, and the initial trace faces to the substrate when attaching the redistribution wiring structure to the substrate.

16. The manufacturing method for an electronic device claimed in claim 15, wherein the rigid board is removed from one surface the redistribution wiring structure in the step of removing at least partial of the base substrate, and at least one pad are formed on the surface of the redistribution wiring structure, and wherein the redistribution wiring structure denotes the redistribution structure.

17. The manufacturing method for an electronic device as claimed in claim 13, wherein one or more thin-filmed devices are formed on the redistribution structure before or after the step of attaching the redistribution structure on the base substrate, and the one or more thin-filmed devices are electrically connected to the RDL trace.

18. The manufacturing method for an electronic device as claimed in claim 7, wherein the redistribution structure includes one or more sub-trace layer(s) stacked thereover.

19. The manufacturing method for an electronic device as claimed in claim 7, wherein a coefficient of thermal expansion (CTE) of the substrate and the redistribution structure is respectively defined; and a difference between the CTE of the substrate and the CTE of the redistribution structure is no greater than 30 ppm/° C.

20. The manufacturing method for an electronic device as claimed in claim 7, wherein the substrate is a glass substrate, a ceramic substrate, a bismaleimide triazin laminated (BT) substrate, a fiberglass-reinforced epoxy-laminated (FR4) substrate, an ajinomoto build-up film (ABF) substrate, or Rogers substrate.
